(19) United States
(12) Patent Application Publication
(10) Pub. No.: US 2023/0159821 A1
(43) Pub. Date: May 25, 2023

(54) FABRICATION OF THE SI QUANTUM DOTS BY UV METHOD AND THEREOF

(71) Applicant: ISTANBUL SABAHATTIN ZAIM ÜNIVERSITESI, Istanbul (TR)

(72) Inventor: Osman ARSLAN, Istanbul (TR)

(73) Assignee: ISTANBUL SABAHATTIN ZAIM ÜNIVERSITESI, Istanbul (TR)

(21) Appl. No.: 17/921,455

(22) PCT Filed: May 20, 2020
(86) PCT No.: PCT/TR2020/050435

§ 371 Date: Oct. 26, 2022

(30) Foreign Application Priority Data
Apr. 30, 2020 (TR) 2020/06818

(51) Int. Cl. C09K 11/59; H10K 50/115

(52) U.S. Cl. CPC C09K 11/59; H10K 50/115; B82Y 30/00

(57) ABSTRACT

Production of silicon quantum dots by an ultraviolet method with carboxylic acid or carboxlic acid salt reactants, which can be modified for further applications with possible methods in an aqueous medium with a silicon precursor using the ultraviolet (UV-Vis) technique.

### TECHNICAL FIELD

The present invention is related with a method for a Silicon quantum dot production in an aqueous environment with a silicon precursor using an ultraviolet (UV-Vis) technique. Obtained Si QD can be covalently bonded by interacting at the molecular level with surfaces such as ceramics, polymers, glass, metal and wood. It also relates to the production method of silicon quantum particles (Si QD), which their surfaces can be varied with the desired surface functional group during or after the irradiation.

### BACKGROUND OF THE INVENTION

Semiconductor nanostructures showing the quantum confinement effect with particle size changing between 2-10 nm are generally called quantum particles. As the dimensions of nanoparticle or quantum particles are smaller than an electron wavelength (about 10 nm), an electron movement as an effect of particle size is greatly influenced by the finite, constrained nature of quantum particle size. These quantum particles show some chemical and physical properties which is generally not usual in amorphous materials. Quantum particles consist of hundreds or thousands of atoms and depending on the size of these structures, they have some features of quantum confinement such as band gap energy or size dependent photoluminescence.

Excited electrons are transferred into the conductive band from the valence band by the absorbed energy. Respectively, excited electrons in the conductivity band should return to the lower energy valence band again if the electrons are not transferred elsewhere. In general, quantum dots emit different colors and wavelengths depending on their size and therefore emission can be in different wavelengths. In addition, different colors or emitted wavelengths of quantum dots show more stable properties when compared to organic structures emissions.

Quantum dots can be utilized in solar cells; Li battery applications, fluorescence marker structures, cell labeling or theranostic applications. Also quantum dot chemical structure can consist of binary or single atoms. This chemical variance in quantum dot structure changes the fluorescence or magnetic properties of the quantum particles in addition to the chemical and surface features.

In the current situation, particle production methods are included in the production of Si QD, especially by the abrasion method from porous silicon wafer or by reducing Si precursors by relatively complicated environments. In addition, a separate modification process may be required for the surface of the Si quantum dots after the particles have been obtained. In the state of the art, a solid porous Si metal plate reacts with HF acid, which is a very hazardous substance.

Present processes may cause various challenges, since it may be necessary to have different gas outflows in the prior art for quantum dot synthesis or it may be necessary to use high temperature methods such as hydrothermal-solvothermal techniques. In many techniques, precursors that are not air-resistant or easily oxidized in air are used. Therefore, widely known techniques contain dangerous side chemicals and the surfaces of the quantum dots must be modified by a secondary process for stabilization. Secondary processes that provide modification are required to overcome the complexity of this situation, but they cause an additional workload and costs time. Therefore, additional processes producing unnecessary additional time and expensive and dangerous chemicals should be neutralized and reduced.

The invention is about the Si QD preparation and firstly precursor and water should be mixed with defined proportions so that it can be a homogeneous solution and is rapidly combined with the carboxylic acid solution prepared in another container. Alcoholic solvents with small carbon numbers can be used optionally. However, time factor is extremely important and it is a fact that if irradiation with UV light (UV-Vis) is not applied to prepared mixture, solution becomes unusable within a few hours. Therefore, prepared solutions are placed under the radiation source (from a certain distance) and they are subjected to irradiation for a certain period of time. In addition to that, carboxylic acid concentration controls the formation of Si QD by irradiation. The resulting Si quantum dots emits visible region depending on the size. After the synthesis, Si QD structures with positively charged functional group is provided due to the precursors nature and the second or third functional groups can be added without changing the visible emission and the modification can be extended in a large band. In this case, fluorescence feature can be transferred on almost every surface by QD modification as desired.

Depending on the nature of the invention, previous disadvantages such as the existing dangerous side effects are eliminated. Modification of the synthesized Si QD surfaces does not require additional surface treatment processes as the modification occurs naturally during the synthesis. In addition, since Si quantum dots are positively charged and they can adhere to the different surfaces and add fluorescence feature tho these surfaces of the materials.

The subject of the invention includes obtaining Si quantum particles by electromagnetic radiation (UV-Vis) and a carboxylic acid compound. After synthesis, Si particles can remain stable for months at low temperatures with convenient storage. Storage temperature can be between +4 OC or −10 OC. After the quantum particles have been synthesized, they can be obtained in the form of powdered SiO2 structures in the 200-500 nm range and after the necessary processes, by modifying the surface with different functional groups mentioned earlier (epoxy, vinyl, octyl, perfluoro, mercapto, propyl . . . ) wide range of functional surfaces can be obtained.

The structural and characteristic features and all the advantages of the invention will be more clearly understood by the following figures and the detailed explanation written with reference to these figures, and therefore this assessment should be made taking these figures and detailed explanation into consideration.

### SUPPORTIVE FIGURES TO HELP DESCRIBE THE INVENTION

FIG. 1: Fluorescence graph of Si quantum dots irradiated for 30 minutes and excited at different wavelengths

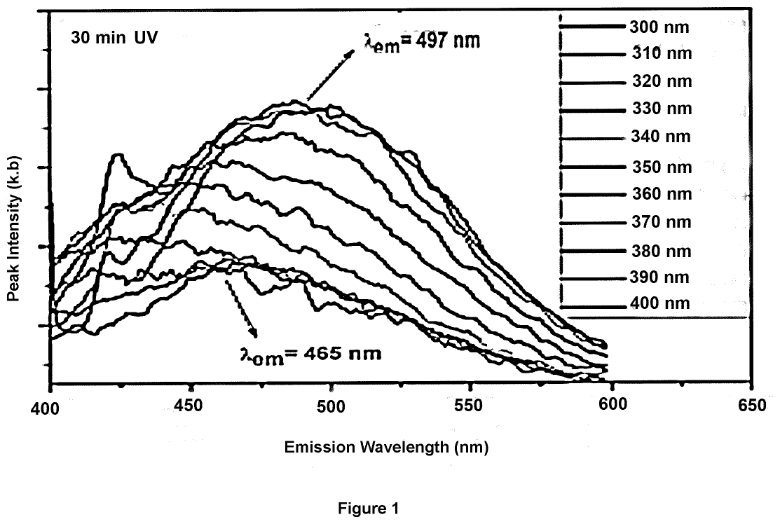

FIG. 2: UV vis graph of Si quantum dots irradiated for 30 minutes

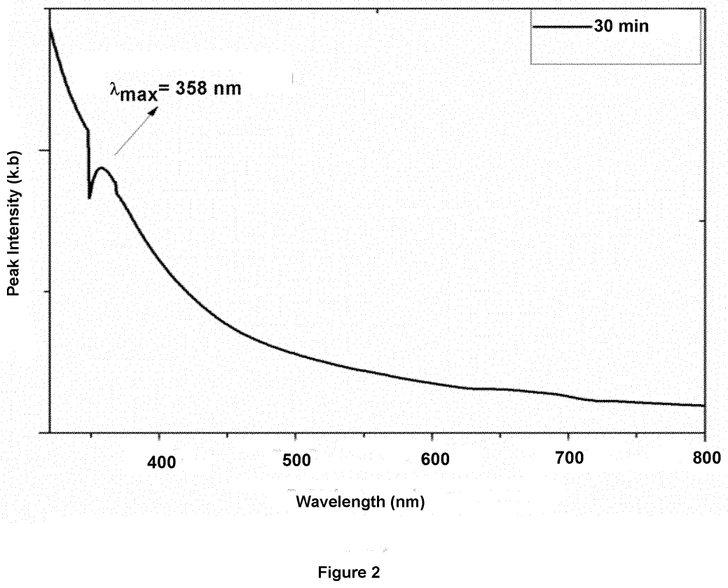

FIG. 3: STEM images of the Si QDS

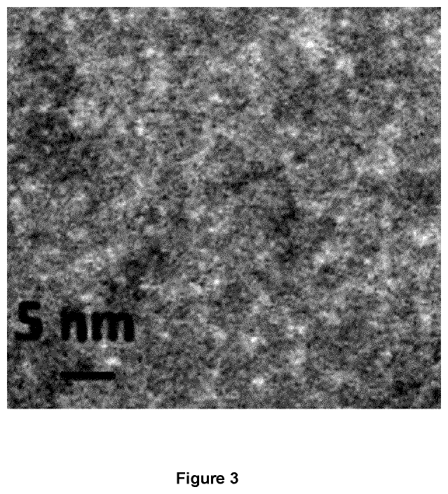

FIG. 4: SEM image of the Si QDs after the SiO2 transformation

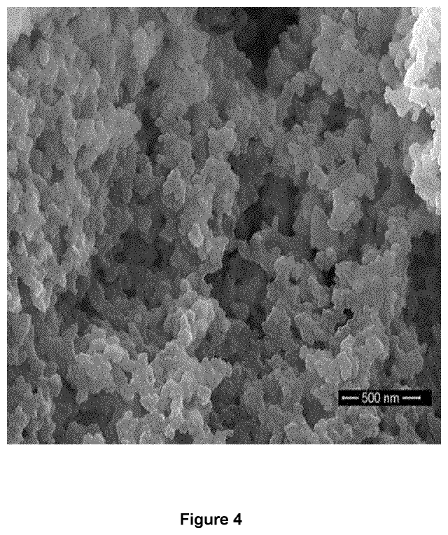

### DETAILED DESCRIPTION OF THE INVENTION

In this detailed explanation, present invention describes the ultraviolet method and the production of silicon quantum dots, their surface groups and conversion of these groups into different functionalities for general nanotechnology applications and utilization of this method without any limiting effect.

Electromagnetic spectrum consists of different wavelengths or energies from another perspective. The UV-Vis zone is located at higher energy than the Infrared zone and lower energy than the X-Ray (X-rays) zone. The present invention explains the formation of Si quantum dots with a Si precursor using the UV-Vis energy region. These Si QDs can be irradiated in the visible area and their surface can be modified in a controlled manner and also the surface of these Si QDs can be replaced with other functional groups. Si quantum dots which are in the range of 2-3 nm carries selectively amino groups on their surface and have positive values in zeta potential measurements. Since oxide quantum dots are very wide, this new feature is a novel result. During the synthesis of Si QD, UV light is used as an energy source for nucleation and growth process together with a carboxylic acid. These acids are generally used as coreactants for their redox capacity with sodium or potassium salts.

The wavelengths of visible range emission of silicon quantum dots can be changed by the UV radiation interaction times as shown in Figures. Si quantum dots obtained in this way can be stored in relative cold environments. With this storage, emission features of the Si QDs can be preserved at synthesized wavelength for several months. Fabricated quantum dots are oxidized to SiO2 nanoparticles as a result of the aqueous medium and non stop condenzation with temperature if it rises. Although the emission peak intensity of the silica particles is partially reduced, emission continues to emerge in the visible region. Also, since these nanoparticles will turn into SiQD/SiO2 core/Shell structure they can be a core agent in nanocomposite industry as the core/Shell structure keeps its original emission in the visible range. For example different building or coating materials can be transformed into visible light emitting nanotechnologic structures. In addition to that, every surface, every particle, every metal structure, every glass surface, organic structures almost any suitable sample can be modified with these quantum dots for novel applications. This allows the synthesized quantum dots to be used as a fluorescent molecular label.

Synthesis of surface-modified silicon quantum dots with UV-Vis technique can be accomplished for a minimum of 30 minutes and from 10 mL to 1 liter in a laboratory environment with an adjusted UV Vis source. For large volumes, the irradiation time may take a little more time than 30 minutes. Therefore, with an easy method, 1 liter of quantum particles can be easily prepared. Thus, one of the biggest problems of quantum dots is solved with this method. Nucleation and growth parameters should be chosen very importantly for calcinogen quantum dots (e.g. CdSe, CdS, PdSe . . . ) which are widely known by the hot injection method. In the Hot Injection method, very high temperatures are required for nucleation and the second component of the quantum dot is generally injected into the reaction medium by a syringe. Consequently, a similar and suitable nucleation allows the production of a small portion of quantum particles, as the temperature drops. With this invention, perfect nucleation and growth can be achieved even for a 1 liter solution. Also, in addition to large amount QD synthesis advantage, surface problems can also be solved. In order to overcome the surface agglomeration problem in this invention, there is a surface chemical structure that is automatically produced during the synthesis. Obtained QD has a modified surface and also this surface is positively charged in aqueous medium. Since organic solvents are not utilized, toxic effects are easily eliminated. In this way, metal, glass, wood, ceramic and plastic surfaces can be covered with different coating methods and transformed as fluorescence nanostructures.

The present invention takes place with aqueous solutions with silane precursor. For changing the surface modification some other silanes may be used based on synthesis technique and synthesis duration. Since long aliphatic structures namely perfluoro groups or octyl groups need longer times for hydrolysis and condensation various pretreatments may be necessary. Therefore, additional modification must be covalently bound to the Si quantum dot by an additional reaction. In these reactions, when two silanes are mixed at the same time, it requires rapid oxidation and control of SiO2 formation. Since Si quantum dot surfaces are modified, the core/shell (Si/SiO2) structure emits visible light with different modifications. This method provides a direct method for Si QD synthesis and since method contains UV light and simple chemicals such as carboxylic acid or sodium, potassium salts of carboxylic acid derivatives, a contrallable medium is formed. Hence, the modification process takes place spontaneously on the synthesized Si QD surfaces without any additional surface treatment. Desired modifications can change QD surface and even hydrophilic structure can be transformed into hydrophobic upon request.

Visible fluorescence emission after irradiation is observed after the Si quantum dot synthesis. While aqueous Si QD is a homogeneous and colorless solution, after the irradiation, colorless solution becomes slightly yellowish but emission in visible region can be selectively stabilized. Therefore time control is crucial and it can provide the wavelength selection in visible region. Optionally, the invention can be applied as coating on fibers such as a nanometer-thick blanket and transfers the radiation to the nanofiber structure.

Fluorescence effects are observed after a certain time period for the Si QDs. At the beginning and early stages of the irradiation solution is colorless but formation of the Si QDs can also be observed with naked eye since solution becomes slightly yellowish. Amax=450-520 range was detected but this range can be expanded with different parameters. Especially modification is easily obtained during the synthesis in this aqueous solution for Si QD.

It is clear that an expert in the fiedl, can demonstrate the novelty of the invention using similar methods and/or apply it to other areas of similar purpose in the field. It is therefore obvious that such methods will lack the criterion of innovation and novelty especially overcoming the side difficulties in the production.

### INDUSTRIAL APPLICATION OF THE INVENTION

The invention is easily applicable to multiple fields of industry. Since these quantum dots will turn into SiQD/SiO2 core/shell structures as the reaction proceed, they can be utilized as nanocomposite structures that provide visible range emission for different building or coating materials. Due to the natural structure of these quantum dots, they can easily interact with surfaces such as ceramic, polymer, glass, metal at the molecular level and also they can be attached to particles, fiber structures, large metal surfaces with covalent bonds and used for sensors, fluorescence applications, labeling, barcodes and many other applications.

1-7. (canceled)

8. A method for fabricating Si quantum dots using a UV-Vis method, comprising:
modifying the quantum dots with different functional groups;
positively charging quantum dots zeta potential in an aqueous environment; and
obtaining a desired concentration and formation of the Si quantum dots through UV radiation emitting visible light, wherein
the concentration and formation are determined by different parameters of the UV radiation;
the quantum dots are sized in a range of 2-3 nm; and
one or more carboxylic acids or Na, K salts of carboxylic acids are used.

9. The method of claim 8, further comprising:
adding quantum dot structures with different functional groups whose surfaces have been previously specified, and
modifying the quantum dot structure with a second or third functional group, wherein visible light emissions remain constant after the modification and the modification can be expanded in a large band.

10. The method of claim 8, further comprising:
extracting an amount of the obtained quantum dots in aqueous environments, wherein the UV-Vis energy belongs to a certain area of electromagnetic radiation.

11. The method of claim 8, further comprising:
irradiating the Si for a minimum of 30 minutes, and
producing 10 ml to 1 L of quantum dots.

12. The method of claim 8, wherein the quantum dots emit visible light of different wavelengths upon excitation.

13. The method of claim 8, further comprising;
using a precursor material, and
preparing the carboxylic acid solution in a container separate from the precursor material, and/or
using various other small carbon alcohol solvents, wherein
the precursor material is a homogeneous aqueous solution that can be combined with the carboxylic acid solution prepared in another container or the various other small carbon alcohol solvents.

14. The method of claim 8, wherein the quantum dots have positively charged surfaces and are attachable to surfaces with negatively charged polymers.
